(19) United States
(12) Patent Application Publication
(10) Pub. No.: US 2016/0351150 A1
(43) Pub. Date: Dec. 1, 2016

(54) SHIFT REGISTER UNIT, SHIFT REGISTER, GATE DRIVING CIRCUIT AND DISPLAY DEVICE

(71) Applicant: BOE TECHNOLOGY GROUP CO., LTD., Beijing (CN)

(72) Inventor: Zhanjie MA, Beijing (CN)

(73) Assignee: BOE TECHNOLOGY GROUP CO., LTD., Beijing (CN)

(21) Appl. No.: 14/771,030

(22) PCT Filed: Mar. 17, 2015
(86) PCT No.: PCT/CN2015/074352

§ 371 Date: Aug. 27, 2015

(30) Foreign Application Priority Data
Nov. 19, 2014 (CN) 201410664680.7

(51) Int. Cl. G09G 3/36; G11C 19/28

(52) U.S. Cl. CPC G09G 3/3677; G11C 19/28; G09G 2310/0286; G09G 2300/0809

(57) ABSTRACT

The shift register unit includes a first module, a second module and a control module, where the first module including a first control transistor is configured to make an output terminal of the shift register unit in a current stage output a high level signal, where a gate electrode of the first control transistor is connected to the control module, a first electrode thereof is connected to a high level signal input terminal, a second electrode thereof is connected to the output terminal; the control module is configured to control on and off states of the first control transistor; and the second module including a second control transistor is configured to make the output terminal of the shift register unit in the current stage output a low level signal, where a gate electrode and a first electrode of the second control transistor are both connected to a low level signal input terminal, and a second electrode thereof is connected to the output terminal.

### CROSS-REFERENCE TO RELATED APPLICATION

This application is the U.S. national phase of PCT Application No. PCT/CN2015/074352 filed on Mar. 17, 2015, which claims a priority to Chinese Patent Application No. 201410664680.7 filed on Nov. 19, 2014, the disclosures of which are incorporated in their entirety by reference herein.

### TECHNICAL FIELD

The present disclosure relates to the field of liquid crystal display technology, and in particular to a shift register unit, a shift register including the shift register unit, a gate driving circuit including the shift register, and a display device including the gate driving circuit.

### BACKGROUND

In an Organic Light-Emitting Diode (OLED for short hereinafter) display device, each pixel may emit light independently to perform a display under control of film transistors. A shift register unit for controlling light emission is required in a gate driving circuit of the OLED display device, where the shift register unit for controlling light emission realizes that the light emission of pixels may always be turned on in a phase of light emission of pixels by outputting a turn-off signal at one pulse period of time and outputting turn-on signals during all the other period of time.

FIG. 1 is a circuit diagram of an existing shift register unit for controlling light emission. As shown in FIG. 1, the shift register unit for controlling light emission includes a first module 1, a second module 2, a first control module 3′ and a second control module 3″. The first module 1 including a first control transistor 10 is configured to make an output terminal 4 of the shift register unit in a current stage output a high level signal, where a first electrode of the first control transistor 10 is connected to a high level signal input terminal 5, a second electrode thereof is connected to the output terminal 4. The second module 2 including a second control transistor 20 is configured to make an output terminal 4 of the shift register unit in the current stage output a low level signal, where a first electrode of the second control transistor 20 is connected to a low level signal input terminal 6, and a second electrode thereof is connected to the output terminal 4. The first control module 3′ and the second control module 3″ are configured to control on and off states of the first control transistor 10 and the second control transistor 20. The first control module 3′ includes an initial signal module 3c′, a first capacitor C_{S0}, and a first sub-module 3a′ and a second sub-module 3b′ connected with the first capacitor C_{S0} in parallel; the second control module 3″ includes a third sub-module 3a″ and a fourth sub-module 3b″; the first sub-module 3a′ and the second sub-module 3b′ are connected to a gate electrode of the first control transistor 10, to control on and off states of the first control transistor 10. In addition, the first sub-module 3a′ and the second sub-module 3b′ are further connected to the third sub-module 3a″, to control on and off states of each transistor in the third sub-module 3a″; the third sub-module 3a″ and the fourth sub-module 3b″ are connected to a gate electrode of the second control transistor 20, to control on and off states of the second control transistor 20. To be specific, the initial signal module 3c′ includes a signal control transistor 30; the first sub-module 3a′ includes a first transistor 31, a second transistor 32, a third transistor 33 and a second capacitor C_{S1}; the second sub-module 3b′ includes a fourth transistor 34; the third sub-module 3a″ includes a fifth transistor 35 and a sixth transistor 36; the fourth sub-module 3b″ includes a seventh transistor 37 and a third capacitor C_{S2}; a connection relation of the above transistors is shown in FIG. 1.

A working principle of the shift register unit for controlling light emission may be illustrated hereinafter in conjunction with FIG. 1 and FIG. 2 in the case that each transistor in the shift register unit for controlling light emission and the film transistor for controlling the light emission of pixels are P-type transistors. To be specific, as shown in FIG. 2, in a first phase a, an initial signal input into an initial signal input terminal 8 is at a low level, a first clock signal input into a first clock signal input terminal 7 is at a low level, and a second clock signal input into a second clock signal input terminal 9 is at a high level. In this case, the first control transistor 10 and each transistor in the third sub-module 3a″ are in off states under control of the second sub-module 3b′, and the second control transistor 20 is in an on state under control of the fourth sub-module 3b″, thereby the low level signal input into the low level signal input terminal 6 may be output from the output terminal 4 via the second module 2, i.e., a turn-on signal may be output from the output terminal 4. In a second phase b, the initial signal turns to a high level, the first clock signal turns to a high level, and the second clock signal turns to a low level. In this case, the first control transistor 10 and each transistor in the third sub-module 3a″ are in on states under control of the second sub-module 3b′, whereby the second control transistor 20 may be in an off state under control of the third sub-module 3a″, thereby the high level signal input into the high level signal input terminal 5 may be output from the output terminal 4 via the first module 1, i.e., a turn-off signal may be output from the output terminal 4. In a third phase c, the initial signal maintains in a high level, the first clock signal turns to a low level, and the second clock signal turns to a high level. In this case, the first control transistor 10 and each transistor in the third sub-module 3a″ are in off states under control of the first sub-module 3a′, and the second control transistor 20 is in an on state under control of the fourth sub-module 3b″, thereby the low level signal input into the low level signal input terminal 6 may be output from the output terminal 4 via the second module 2, i.e., a turn-on signal may be output from the output terminal 4. In the fourth phase d, the initial signal maintains in a high level, the first clock signal turns to a high level, and the second clock signal turns to a low level. In this case, the first control transistor 10 and each transistor in the third sub-module 3a″ are in off states under control of the first sub-module 3a′, and the second control transistor 20 is in an on state under control of the fourth sub-module 3b″, thereby the low level signal input into the low level signal input terminal 6 may be output from the output terminal 4 via the second module 2, i.e., a turn-on signal may be output from the output terminal 4. In the subsequent phases, the third phase c and the fourth phase d may be repeated continually, whereby all the signals output from the output terminal 4 may be turn-on signals.

In the shift register unit for controlling light emission hereinabove, the signal output of the shift register unit for controlling light emission is controlled by using a plurality of transistors (totally 10), i.e., the turn-off signal is output only at one pulse period of time, and the turn-on signals are output during the other period of time, therefore the shift register unit for controlling light emission may occupy a lot of space (i.e., occupy a wider border), and then it may not facilitate to realize a narrow border of a display device.

### SUMMARY

The present disclosure is to solve at least one of the technical issues existing in the prior art, where a shift register unit, a shift register, a gate driving circuit and a display device are provided. An amount of transistors in the shift register unit may be reduced, thereby reducing a space occupied by the shift register unit (i.e., the border may be narrower) and then helping to realize a narrow border of a display device.

To achieve the objective of the present disclosure, a shift register unit is provided by the present disclosure, including a first module, a second module and a control module, where the first module including a first control transistor is configured to make an output terminal of the shift register unit in a current stage output a high level signal, where a gate electrode of the first control transistor is connected to the control module, a first electrode of the first control transistor is connected to a high level signal input terminal, a second electrode of the first control transistor is connected to the output terminal of the shift register unit in the current stage; the control module is configured to control on and off states of the first control transistor; and the second module including a second control transistor is configured to make an output terminal of the shift register unit of the stage output a low level signal, where a gate electrode and a first electrode of the second control transistor are both connected to a low level signal input terminal, and a second electrode of the second control transistor is connected to the output terminal of the shift register unit in the current stage.

The control module includes an initial signal module, a first capacitor and a first control module and a second control module connected with the first capacitor in parallel; where the initial signal module is configure to provide an initial signal to the first capacitor, the first control module and the second control module; a first end of the first capacitor is connected to the initial signal module, and a second end thereof is connected to the gate electrode of the first control transistor; the first control module is configured to control the on and off states of the first control transistor based on the initial signal and a first clock signal input into a first clock signal input terminal; and the second control module is configured to control on and off states of the first control transistor based on the initial signal and a second clock signal input into a second clock signal input terminal.

The initial signal module includes a signal control transistor, where a gate electrode of the signal control transistor is connected to the first clock signal input terminal, a first electrode of the signal control transistor is connected to an initial signal input terminal, and a second electrode of the signal control transistor is connected to the first end of the first capacitor, the first control module and the second control module.

The first control module includes a second capacitor, a first transistor, a second transistor and a third transistor; where a gate electrode and a first electrode of the first transistor are both connected to the first clock signal input terminal, a second electrode of the first transistor is connected to a second electrode of the second transistor and a gate electrode of the third transistor; a gate electrode of the second transistor is connected to the second electrode of the signal control transistor, a first electrode of the second transistor is connected to the high level signal input terminal, and the second electrode of the second transistor is connected to a gate electrode of the third transistor; and the gate electrode of the third transistor is connected to a first end of the second capacitor, a second end of the second capacitor is connected to the high level signal input terminal, a first electrode of the third transistor is connected to the high level signal input terminal, and a second electrode of the third transistor is connected to the gate electrode of the first control transistor and the second end of the first capacitor.

The second control module includes a fourth transistor, where a gate electrode of the fourth transistor is connected to the second electrode of the signal control transistor and the first end of the first capacitor, a first end of the fourth transistor is connected to the second clock signal input terminal, and a second electrode of the fourth transistor is connected to the gate electrode of the first control transistor and the second terminal of the first capacitor.

A shift register is further provided by the present disclosure as another technical scheme, including cascading multiple stages of the shift register unit hereinabove provided by the present disclosure.

A gate driving circuit is further provided by the present disclosure as another technical scheme, including the shift register hereinabove provided by the present disclosure.

A display device is provided by the present disclosure as another technical scheme, including a gate electrode and the gate driving circuit hereinabove provided by the present disclosure.

The present disclosure has the following advantages:

In the shift register unit provided by the present disclosure, the gate electrode of the second control transistor is connected to the low level signal input terminal, i.e., on and off states of the second control transistor is directly controlled by the low level signal, whereby it is not required to arrange specially an additional transistor to control the on and off states of the second control transistor respectively. Compared with the prior art, an amount of the transistors in the shift register unit provided by the present disclosure is reduced, thereby reducing a space required to be occupied by the shift register unit and then facilitating to realize a narrow border of the display device.

The shift register provided by the present disclosure includes the shift register unit hereinabove provided by the present disclosure, whereby it is not required to arrange specially an additional transistor to control the on and off states of the second control transistor respectively. Compared with the prior art, an amount of the transistors is reduced, thereby reducing a space required to be occupied by the shift register and then helping to realize a narrow border of the display device.

The gate driving circuit provided by the present disclosure includes the shift register hereinabove provided by the present disclosure, whereby it is not required to arrange specially an additional transistor to control the on and off states of the second control transistor respectively. Compared with the prior art, an amount of the transistors is reduced, thereby reducing a space required to be occupied by the gate driving circuit and then helping to realize a narrow border of the display device.

The display device provided by the present disclosure includes the gate driving circuit hereinabove provided by the present disclosure, thereby reducing a space required to be occupied by the gate driving circuit and then helping to realize a narrow border of the display device.

### BRIEF DESCRIPTION OF THE DRAWINGS

The drawings being a part of the specification are to provide a further understanding of the present disclosure. The present disclosure may be illustrated by the following embodiments in conjunction with the drawings, but that is not meant to limit the scope of the present disclosure.

FIG. 1 is a circuit diagram of an existing shift register unit for controlling light emission;

FIG. 2 is a time sequence diagram showing each signal in the shift register unit for controlling light emission in the case that each transistor in the shift register unit for controlling light emission and a film transistor for controlling light emission of pixels are P-type transistors;

FIG. 3 is a circuit diagram of a shift register unit according to an embodiment of the present disclosure;

FIG. 4 is a time sequence diagram showing each signal in the shift register unit in the case that each transistor in the shift register unit and the film transistor for controlling the light emission of pixels are P-type transistors;

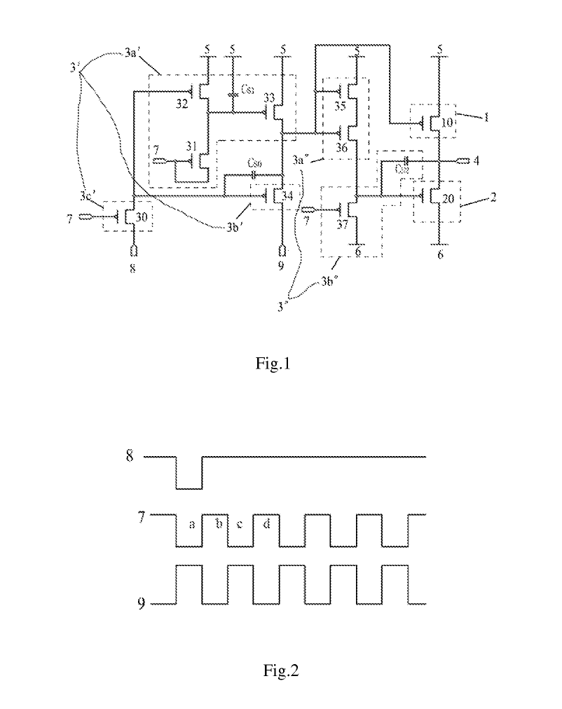

### DETAILED DESCRIPTION

The embodiment of the present disclosure may be described hereinafter in details in conjunction with the drawings. It should be understood that the embodiment described herein is merely an illustration of the present disclosure rather than a limitation thereof.

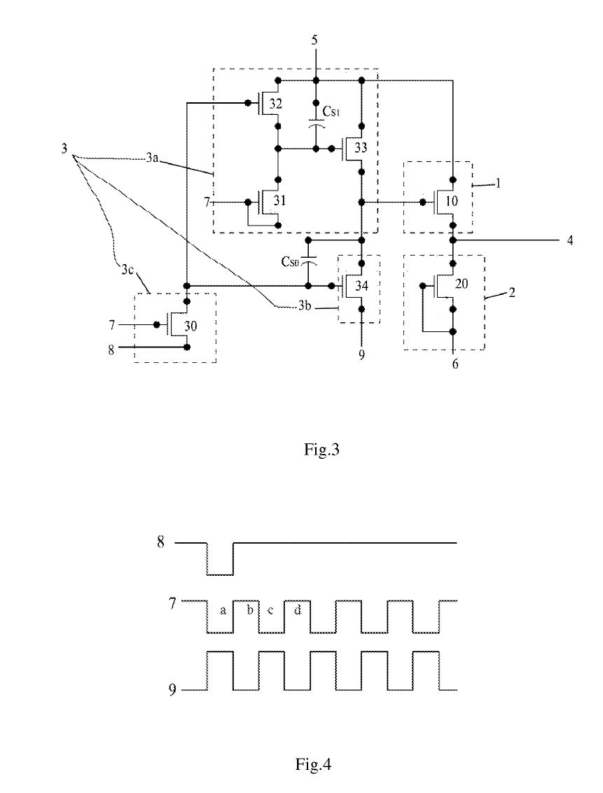

FIG. 3 is a circuit diagram of a shift register unit according to an embodiment of the present disclosure. In this embodiment, as shown in FIG. 3, a shift register unit includes a first module 1, a second module 2 and a control module 3. The first module 1 including a first control transistor 10 is configured to make an output terminal 4 of the shift register unit in a current stage output a high level signal, where a gate electrode of the first control transistor 10 is connected to the control module 3, a first electrode of the first control transistor 10 is connected to a high level signal input terminal 5, a second electrode of the first control transistor 10 is connected to the output terminal 4 of the shift register unit in the current stage; the control module 3 is configured to control on and off states of the first control transistor 10; and the second module 2 including a second control transistor 20 is configured to make an output terminal 4 of the shift register unit in the current stage output a low level signal, where a gate electrode and a first electrode of the second control transistor 20 are both connected to a low level signal input terminal 6, and a second electrode of the second control transistor 20 is connected to the output terminal 4 of the shift register unit in the current stage.

In this embodiment, the term “first electrode” represents a source electrode, and the term “second electrode” represents a drain electrode; alternatively, the term “first electrode” represents a drain electrode, and the term “second electrode” represents a source electrode.

In this embodiment, the gate electrode of the second control transistor 20 is connected to the low level signal input terminal 6, i.e., the on and off states of the second control transistor 20 is directly controlled by a low level signal input into the low level signal input terminal 6, thereby it is not required to arrange specially an additional transistor to control the on and off states of the second control transistor 20 respectively. Compared with the prior art, an amount of the transistors in the shift register unit in this embodiment is reduced, thereby reducing a space occupied by the shift register unit and then facilitating to realize a narrow border of the display device.

The control module 3 includes an initial signal module 3c, a first capacitor C_{S0} and a first control module 3a and a second control module 3b connected with the first capacitor C_{S0} in parallel; the initial signal module 3c is configure to provide an initial signal to the first capacitor C_{S0}, the first control module 3a and the second control module 3b, where a first terminal of the first capacitor C_{S0} is connected to the initial signal module 3c, and a second terminal thereof is connected to the gate electrode of the first control transistor 10; the first control module 3a is configured to control on and off states of the first control transistor 10 based on the initial signal and a first clock signal input into a first clock signal input terminal 7; and the second control module 3b is configured to control on and off states of the first control transistor 10 based on the initial signal and a second clock signal input into a second clock signal input terminal 9.

The initial signal module 3c includes a signal control transistor 30, where a gate electrode of the signal control transistor 30 is connected to the first clock signal input terminal 7, a first electrode of the signal control transistor 30 is connected to an initial signal input terminal 8, and a second electrode of the signal control transistor 30 is connected to the first terminal of the first capacitor C_{S0}, the first control module 3a and the second control module 3b respectively.

The first control module 3a includes a first transistor 31, a second transistor 32 and a third transistor 33. A gate electrode and a first electrode of the first transistor 31 are both connected to the first clock signal input terminal 7, a second electrode of the first transistor 31 is connected to a second electrode of the second transistor 32 and a gate electrode of the third transistor 33; a gate electrode of the second transistor 32 is connected to the second electrode of the signal control transistor 30, a first electrode of the second transistor 32 is connected to the high level signal input terminal 5, and the second electrode of the second transistor 32 is connected to a gate electrode of the third transistor 33; and the gate electrode of the third transistor 33 is connected to a first end of the second capacitor C_{S1}, a second end of the second capacitor C_{S1} is connected to the high level signal input terminal 5, a first electrode of the third transistor 33 is connected to the high level signal input terminal 5, and a second electrode of the third transistor 33 is connected to the gate electrode of the first control transistor 10 and the second end of the first capacitor C_{S0}.

The second control module 3b includes a fourth transistor 34, where a gate electrode of the fourth transistor 34 is connected to the second electrode of the signal control transistor 30 and the first end of the first capacitor C_{S0}, a first electrode of the fourth transistor 34 is connected to the second clock signal input terminal 9, and a second electrode of the fourth transistor 34 is connected to the gate electrode of the first control transistor 10 and the second end of the first capacitor C_{S0}.

A working principle of the shift register unit may be illustrated hereinafter in conjunction with FIG. 3 and FIG. 4 in the case that each transistor in the shift register unit and the film transistor for controlling the light emission of pixels are P-type transistors. To be specific, as shown in FIG. 3 and FIG. 4, in a first phase a, an initial signal input into the initial signal input terminal 8 is at a low level, a first clock signal input into the first clock signal input terminal 7 is at a low level, and a second clock signal input into the second clock signal input terminal 9 is at a high level. In this case, the signal control transistor 30 and the first transistor 31 are turned on; the initial signal charges the first capacitor C_{S0} and maintains charges on the first capacitor C_{S0}, and the initial signal is input into the gate electrodes of the second transistor 32 and the fourth transistor 34, whereby the second transistor 32 and the fourth transistor 34 may be turned on; in a case that the second transistor 32 is turned on, a high level signal input into the high level signal input terminal 5 may be input into the gate electrode of the third transistor 33 via the first and the second electrodes of the second transistor 32, whereby the third transistor 33 may be turned off; in a case that the fourth transistor 34 is turned on, the second clock signal may be input into the gate electrode of the first control transistor 10, whereby the first control transistor 10 may be turned off. In this process, a low level signal is input into the gate electrode of the second control transistor 20 via the low level signal input terminal 6, and then the second control transistor 20 may be turned on, thereby the output terminal 4 of the shift register unit may output a low level signal, i.e., the output terminal 4 may output a turn-on signal.

In the second phase b, the initial signal turns to a high level, the first clock signal turns to a high level, and the second clock signal turns to a low level. In this case, the signal control transistor 30 and the first transistor 31 are turned off, and the initial signal in the first phase a maintained by the first capacitor C_{S0} is input into the gate electrodes of the second transistor 32 and the fourth transistor 34 by the first capacitor C_{S0}, whereby the second transistor 32 and the fourth transistor 34 may be turned on; in a case that the second transistor 32 is turned on, the high level signal input into the high level signal input terminal 5 may be input into the gate electrode of the third transistor 33 and the first end of the second capacitor C_{S1} via the first and the second electrodes of the second transistor 32, whereby the third electrode 33 may be turned off, and the high level signal may charge the second capacitor C_{S1} and maintain the charges thereon, in a case that the fourth transistor 34 is turned on, the second clock signal may be input into the gate electrode of the first control transistor 10 via the first and the second electrodes of the fourth transistor 34, whereby the first control transistor 10 may be turned on. In this process, the low level signal is input into the gate electrode of the second control transistor 20, whereby the second control transistor 20 may still remain an on state; however, the first control transistor 10 has been turned on, and a voltage of the high level signal is higher than a voltage of the low level signal, thereby the shift register unit may output a high level signal, i.e., the output terminal 4 may output a turn-off signal.

In the third phase c, the initial signal maintains at a high level, the first clock signal turns to a low level, and the second clock signal turns to a high level. In this case, the signal control transistor 30 and the first transistor 31 are turned on, the initial signal charges the first capacitor C_{S0} and maintains charges thereon, and then the initial signal is input into the gate electrodes of the second transistor 32 and the fourth transistor 34, whereby the second transistor 32 and the fourth transistor 34 may be turned off; in a case that the first transistor 31 is turned on, the first clock signal may be input into the gate electrode of the third transistor 33 via the first and the second electrodes of the first transistor 31, whereby the third transistor 33 may be turned on; in a case that the third transistor 33 is turned on, the high level signal input into the high level signal input terminal 5 may be input into the gate electrode of the first control transistor 10 via the first and the second electrodes of the third transistor 33, whereby the first control transistor 10 may be turned off; meanwhile, the high level signal may further charge the second capacitor C_{S1} and maintains charges thereon. In this process, the low level signal is input into the gate electrode of the second control transistor 20, whereby the second control transistor 20 may still remain turned on, thereby the shift register unit may output a low level signal, i.e., the output terminal 4 may output a turn-on signal.

In the fourth phase d, the initial signal holds a high level, the first clock signal turns to a high level, and the second clock signal turns to a low level. In this case, the signal control transistor 30 and the first transistor 31 are turned off, and the initial signal in the third phase c maintained by the first capacitor C_{S0} is input into the gate electrodes of the second transistor 32 and the fourth transistor 34 by the first capacitor C_{S0}, whereby the second transistor 32 and the fourth transistor 34 may be turned off; the high level signal in the third phase c maintained by the second capacitor C_{S1} is input into the gate electrode of the third transistor 33 by the second capacitor C_{S1}, whereby the third transistor 33 may be turned off; the initial signal in the third phase c maintained by the first capacitor C_{S0} is input into the gate electrode of the first control transistor 10 by the first capacitor C_{S0}, whereby the first control transistor 10 may be turned off. In this process, the low level signal is input into the gate electrode of the second control transistor 20, whereby the second control transistor 20 may still remain an on state, thereby the shift register unit may output a low level signal, i.e., the output terminal 4 may output a turn-on signal. In the subsequent phases, the third phase c and the fourth phase d may be repeated continually, whereby all the signals output by the output terminal 4 may be turn-on signals.

The working principle of the shift register unit is illustrated hereinabove in the case that each transistor in the shift register unit and the film transistor for controlling the light emission of pixels are P-type transistors, however the transistor in the shift register unit and the film transistor for controlling the light emission of pixels are not limited to P-type transistors. For example, each transistor in the shift register unit and the film transistor for controlling the light emission of pixels may be N-type transistors alternatively. In this case, by controlling the time sequences of the initial signal, the first clock signal and the second clock signal, the first control transistor 10 may be turned off only at one pulse period of time and may remains an on state during other period of time, thereby the shift register unit may output a turn-off signal only at one pulse period of time and may output turn-on signals during other period of time.

In the shift register unit provided by the present disclosure, the gate electrode of the second control transistor 20 is connected to the low level signal input terminal 6, i.e., the on and off states of the second control transistor 20 is directly controlled by the low level signal, thereby it is not required to arrange specially an additional transistor to control the on and off states of the second control transistor 20. Compared with the prior art, an amount of the transistors in the shift register unit provided by the present disclosure is reduced, thereby reducing a space occupied by the shift register unit and then facilitating to realize a narrow border of the display device.

A shift register is further provided by the present disclosure as another technical scheme, including a plurality of stages of the shift register units connected in series hereinabove provided by the present disclosure.

A gate driving circuit is further provided by the present disclosure as another technical scheme, including the shift register hereinabove provided by the present disclosure.

The gate driving circuit provided by the present disclosure includes the shift register hereinabove provided by the present disclosure, whereby it is not required to arrange specially an additional transistor to control the on and off state of the second control transistor respectively. Compared with the prior art, an amount of the transistors is reduced, thereby reducing a space occupied by the shift register and the gate driving circuit and then facilitating to realize a narrow border of a display device.

A display device is provided by the present disclosure as another technical scheme, including a gate electrode and the gate driving circuit hereinabove provided by the present disclosure.

To be specific, the display device is an OLED display device.

The display device provided by the present disclosure includes the gate driving circuit hereinabove provided by the present disclosure, where a space required to be occupied by the gate driving circuit may be reduced, thereby facilitating to realize a narrow border of a display device.

It may be understood that, the above embodiments are merely the exemplary embodiments for illustrating a principle of the present disclosure, but the present disclosure is not limited thereto. Those skilled in the art may make various modifications and improvements without departing from the spirit and essence of the present disclosure, and these modifications and improvements may also fall into the scope of the present disclosure.

1. A shift register unit, comprising a first module, a second module and a control module, wherein the first module comprising a first control transistor is configured to make an output terminal of the shift register unit in a current stage output a high level signal, wherein a gate electrode of the first control transistor is connected to the control module, a first electrode of the first control transistor is connected to a high level signal input terminal, a second electrode of the first control transistor is connected to the output terminal of the shift register unit in the current stage;
the control module is configured to control on and off states of the first control transistor; and
the second module comprising a second control transistor is configured to make the output terminal of the shift register unit in the current stage output a low level signal, wherein a gate electrode and a first electrode of the second control transistor are both connected to a low level signal input terminal, and a second electrode of the second control transistor is connected to the output terminal of the shift register unit in the current stage.

2. The shift register unit according to claim 1, wherein the control module comprises an initial signal module, a first capacitor and a first control module and a second control module connected with the first capacitor in parallel;
wherein the initial signal module is configured to provide an initial signal to the first capacitor, the first control module and the second control module;
a first end of the first capacitor is connected to the initial signal module, and a second end of the first capacitor is connected to the gate electrode of the first control transistor;
the first control module is configured to control on and off states of the first control transistor based on the initial signal and a first clock signal input into a first clock signal input terminal; and
the second control module is configured to control on and off states of the first control transistor based on the initial signal and a second clock signal input into a second clock signal input terminal.

3. The shift register unit according to claim 2, wherein the initial signal module comprises a signal control transistor, wherein a gate electrode of the signal control transistor is connected to the first clock signal input terminal, a first electrode of the signal control transistor is connected to an initial signal input terminal, and a second electrode of the signal control transistor is connected to the first end of the first capacitor, the first control module and the second control module.

4. The shift register unit according to claim 3, wherein the first control module comprises a second capacitor, a first transistor, a second transistor and a third transistor;
wherein a gate electrode and a first electrode of the first transistor are both connected to the first clock signal input terminal, a second electrode of the first transistor is connected to a second electrode of the second transistor and a gate electrode of the third transistor;
a gate electrode of the second transistor is connected to the second electrode of the signal control transistor, a first electrode of the second transistor is connected to the high level signal input terminal, and the second electrode of the second transistor is connected to a gate electrode of the third transistor; and
the gate electrode of the third transistor is connected to a first end of the second capacitor, a second end of the second capacitor is connected to the high level signal input terminal, a first electrode of the third transistor is connected to the high level signal input terminal, and a second electrode of the third transistor is connected to the gate electrode of the first control transistor and the second end of the first capacitor.

5. The shift register unit according to claim 4, wherein the second control module comprises a fourth transistor, wherein a gate electrode of the fourth transistor is connected to the second electrode of the signal control transistor and the first end of the first capacitor, a first electrode of the fourth transistor is connected to the second clock signal input terminal, and a second electrode of the fourth transistor is connected to the gate electrode of the first control transistor and the second end of the first capacitor.

6. A shift register, comprising multiple stages of the shift register unit according to claim 1.

7. A gate driving circuit, comprising the shift register according to claim 6.

8. A display device, comprising a gate electrode and the gate driving circuit according to claim 7.

9. The shift register according to claim 6, wherein the control module comprises an initial signal module, a first capacitor and a first control module and a second control module connected with the first capacitor in parallel;
wherein the initial signal module is configured to provide an initial signal to the first capacitor, the first control module and the second control module;
a first end of the first capacitor is connected to the initial signal module, and a second end of the first capacitor is connected to the gate electrode of the first control transistor;
the first control module is configured to control on and off states of the first control transistor based on the initial signal and a first clock signal input into a first clock signal input terminal; and
the second control module is configured to control on and off states of the first control transistor based on the initial signal and a second clock signal input into a second clock signal input terminal.

10. The shift register according to claim 9, wherein the initial signal module comprises a signal control transistor, wherein a gate electrode of the signal control transistor is connected to the first clock signal input terminal, a first electrode of the signal control transistor is connected to an initial signal input terminal, and a second electrode of the signal control transistor is connected to the first end of the first capacitor, the first control module and the second control module.

11. The shift register according to claim 10, wherein the first control module comprises a second capacitor, a first transistor, a second transistor and a third transistor;
wherein a gate electrode and a first electrode of the first transistor are both connected to the first clock signal input terminal, a second electrode of the first transistor is connected to a second electrode of the second transistor and a gate electrode of the third transistor;
a gate electrode of the second transistor is connected to the second electrode of the signal control transistor, a first electrode of the second transistor is connected to the high level signal input terminal, and the second electrode of the second transistor is connected to a gate electrode of the third transistor; and
the gate electrode of the third transistor is connected to a first end of the second capacitor, a second end of the second capacitor is connected to the high level signal input terminal, a first electrode of the third transistor is connected to the high level signal input terminal, and a second electrode of the third transistor is connected to the gate electrode of the first control transistor and the second end of the first capacitor.

12. The shift register according to claim 11, wherein the second control module comprises a fourth transistor, wherein a gate electrode of the fourth transistor is connected to the second electrode of the signal control transistor and the first end of the first capacitor, a first electrode of the fourth transistor is connected to the second clock signal input terminal, and a second electrode of the fourth transistor is connected to the gate electrode of the first control transistor and the second end of the first capacitor.
